(19) United States
(12) Patent Application Publication
(10) Pub. No.: US 2021/0391528 A1
(43) Pub. Date: Dec. 16, 2021

(54) INTEGRATED STRUCTURE OF CRYSTAL RESONATOR AND CONTROL CIRCUIT AND INTEGRATION METHOD THEREFOR

(71) Applicant: NINGBO SEMICONDUCTOR INTERTIONAL CORPORATION (SHANGHAI BRANCH), Shanghai (CN)

(72) Inventor: Xiaoshan QIN, Ningbo, Zhejiang (CN)

(21) Appl. No.: 17/419,449

(22) PCT Filed: Nov. 5, 2019
(86) PCT No.: PCT/CN2019/115647

§ 371 Date: Jun. 29, 2021

(30) Foreign Application Priority Data
Dec. 29, 2018 (CN) 201811647865.1

(51) Int. Cl. H01L 41/311; H01L 41/293; H01L 41/23; H01L 41/04; H01L 41/09; H01L 41/047; H01L 41/053

(52) U.S. Cl. CPC H01L 41/311; H01L 41/293; H01L 41/23; H01L 41/053; H01L 41/0973; H01L 41/0472; H01L 41/042

(57) ABSTRACT

An integrated structure of a crystal resonator and a control circuit (110) and an integrated method therefor. Integration of the crystal resonator with the control circuit (110) is accomplished by forming, in a device wafer (100) containing the control circuit, a lower cavity (120) with an opening exposed at a back side of the device wafer (100), forming a piezoelectric vibrator (500) on the back side of the device wafer (100) and electrically connecting the piezoelectric vibrator (500) to the control circuit (110) in the device wafer (100) from the back side of the device wafer (100). The crystal resonator is more compact in size, less power-consuming and easier to integrate with other semiconductor components with a higher degree of integration.

### TECHNICAL FIELD

The present invention relates to the technical field of semiconductor and, in particular, to an integrated structure of crystal resonator and control circuit and an integration method therefor.

### BACKGROUND

A crystal resonator is a device operating on the basis of inverse piezoelectricity of a piezoelectric crystal. As key components in crystal oscillators and filters, crystal resonators have been widely used to create high-frequency electrical signals for performing precise timing, frequency referencing, filtering and other frequency control functions that are necessary for measurement and signal processing systems.

The continuous development of semiconductor technology and increasing popularity of integrated circuits has brought about a trend toward miniaturization of various semiconductor components. However, it is difficult to integrate existing crystal resonators with other semiconductor components, and also the sizes of the existing crystal resonators are relatively large.

For example, commonly used existing crystal resonators include surface-mount ones, in which a base is bonded with a metal solder (or an adhesive) to a cover to form a hermetic chamber in which a piezoelectric vibrator is housed. In addition, electrodes for the piezoelectric vibrator are electrically connected to an associated circuit via solder pads or wires. Further shrinkage of such crystal resonators is difficult, and their electrical connection to the associated circuit by soldering or gluing additionally hinders their miniaturization.

### SUMMARY OF THE INVENTION

It is an object of the present invention to provide a method for integrating a crystal resonator with a control circuit, which overcomes the above described problems with conventional crystal resonators, i.e., a bulky size and difficult integration.

To solve the problem, the present invention provides a method for integrating a crystal resonator with a control circuit, comprising:

providing a device wafer in which the control circuit is formed

forming, in the device wafer, a lower cavity with an opening at a back side of the device wafer;

forming, on the back side of the device wafer, a piezoelectric vibrator comprising a top electrode, a piezoelectric crystal and a bottom electrode above the lower cavity;

forming, on the device wafer, a connecting structure configured to connect the top electrode and the bottom electrode of the piezoelectric vibrator to the control circuit; and

forming a cap layer on the back side of the device wafer, wherein the cap layer covers the piezoelectric vibrator, and the cap layer together with the piezoelectric vibrator and the device wafer delimits an upper cavity for the crystal resonator.

It is a further object of the present invention to provide an integrated structure of a crystal resonator and a control circuit, comprising:

a device wafer in which the control circuit and a lower cavity are formed, wherein the lower cavity extends through the device wafer;

a piezoelectric vibrator comprising a top electrode, a piezoelectric crystal and a bottom electrode, wherein the piezoelectric vibrator is formed on the back side of the device wafer and in positional correspondence with the lower cavity;

a connecting structure, formed on the device wafer, configured to electrically connect the top and bottom electrodes of the piezoelectric vibrator to the control circuit; and

a cap layer which is formed on the back side of the device wafer and covers the piezoelectric vibrator, wherein the cap layer together with the piezoelectric vibrator and the device wafer delimits an upper cavity.

In the method of the present invention, the lower cavity is so formed in the device wafer that its opening is exposed at the back side of the device wafer, and the piezoelectric vibrator is then formed on the back side of the device wafer in positional correspondence with the lower cavity. Moreover, planar fabrication processes are performed to form the cap layer that encloses the piezoelectric vibrator within the upper cavity, thus resulting in the formation of the crystal resonator and its integration with the control circuit.

Therefore, the method of the present invention allows the crystal resonator to integrate with other semiconductor components with a higher degree of integration, and compared with traditional crystal resonators (e.g., surface-mount ones), the crystal resonator resulting from the method is more compact, miniaturized in size, less costly and less power-consuming. Further, with the support from the support wafer, the piezoelectric vibrator can be formed on the back side of the device wafer and brought into electrical connection with the control circuit from the back side thereof, allowing higher process flexibility for the piezoelectric vibrator.

### BRIEF DESCRIPTION OF THE DRAWINGS

FIG. 1 shows a flowchart schematically illustrating a method for integrating a crystal resonator with a control circuit according to an embodiment of the present invention.

FIGS. 2a to 2m are schematic representations of structures resulting from steps in a method for integrating a crystal resonator with a control circuit according to an embodiment of the present invention.

FIG. 3 schematically illustrates an integrated structure of a crystal resonator and a control circuit according to an embodiment of the present invention.

In these figures,

100 denotes a device wafer; AA, a device area; 100U, a front side; 100D, a back side; 100A, a substrate wafer; 100B, a dielectric layer; 101, a base layer; 102, a buried oxide layer; 103, a top silicon layer; 110, a control circuit; 111, a first circuit; 111T, a first transistor; 111C, a first interconnecting structure; 112, a second circuit; 112T, a first transistor; 112C, a first interconnecting structure; 120, a lower cavity; 211, a first connecting wire; 212, a second connecting wire; 221, a first conductive plug; 222, a second conductive plug; 300, a planarized layer; 400, a support wafer; 500, a piezoelectric vibrator; 510, a bottom electrode; 520, a piezoelectric crystal; 530, a top electrode; 600, a plastic encapsulation layer; 610, a third conductive plug; 700, an upper cavity; 710, a sacrificial layer; 720, a cap layer; 720a, an opening; 721, a cap material layer; and 730, a closure plug.

### DETAILED DESCRIPTION

The core idea of the present invention is to provide a method for integrating a crystal resonator with a control circuit, in which planar fabrication processes are utilized to integrate the piezoelectric vibrator onto a wafer where the control circuit is formed. This, on the one hand, results in a size reduction of the crystal resonator and, on the other hand, allows an increased degree of integration of the crystal resonator with other semiconductor components.

Specific embodiments of the structure and method proposed in the present invention will be described below in greater detail with reference to the accompanying drawings. Features and advantages of the invention will be more apparent from the following description. Note that the accompanying drawings are provided in a very simplified form not necessarily drawn to exact scale, and their only intention is to facilitate convenience and clarity in explaining the disclosed embodiments.

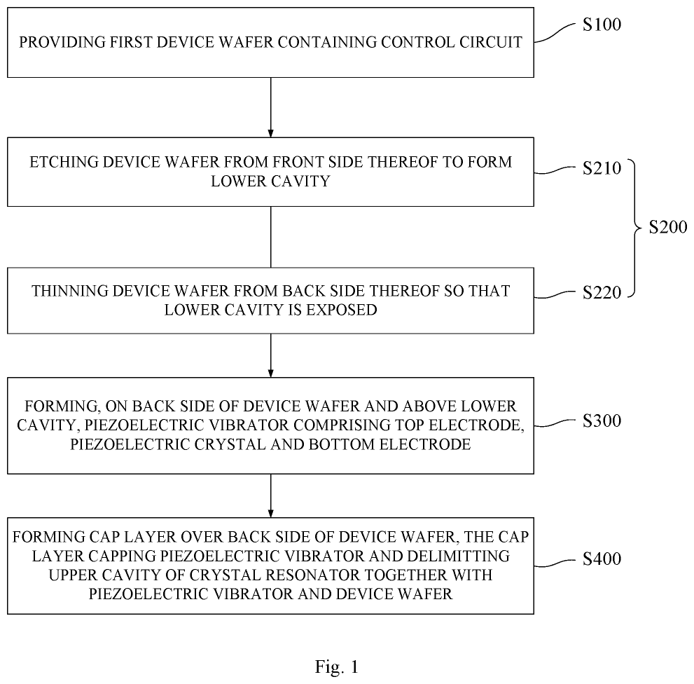

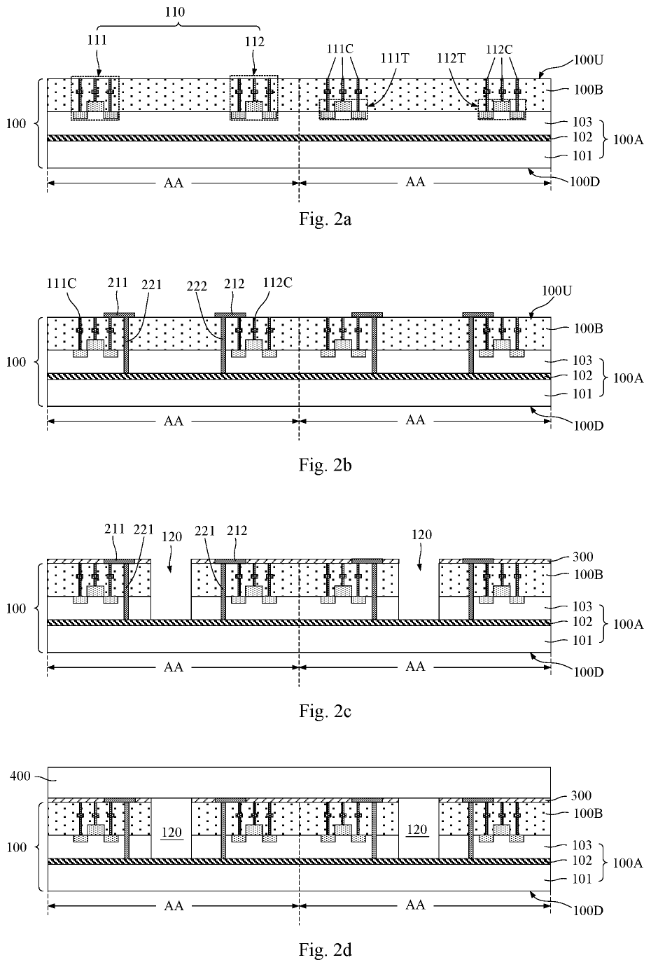

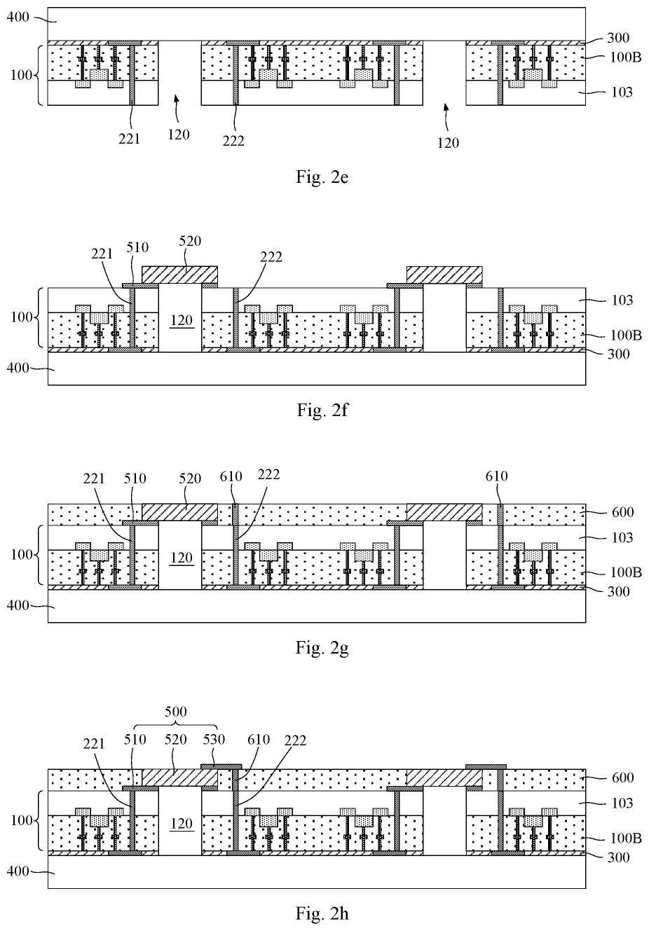

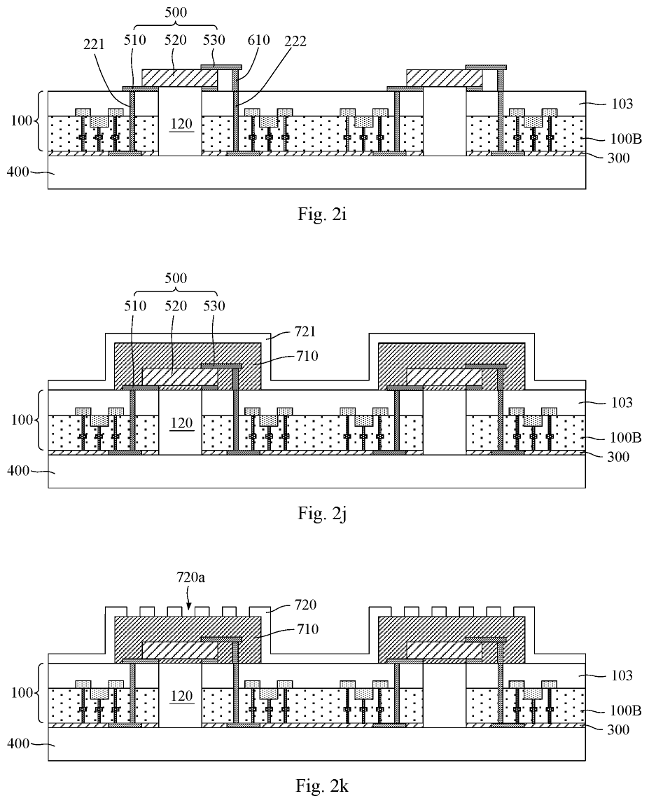

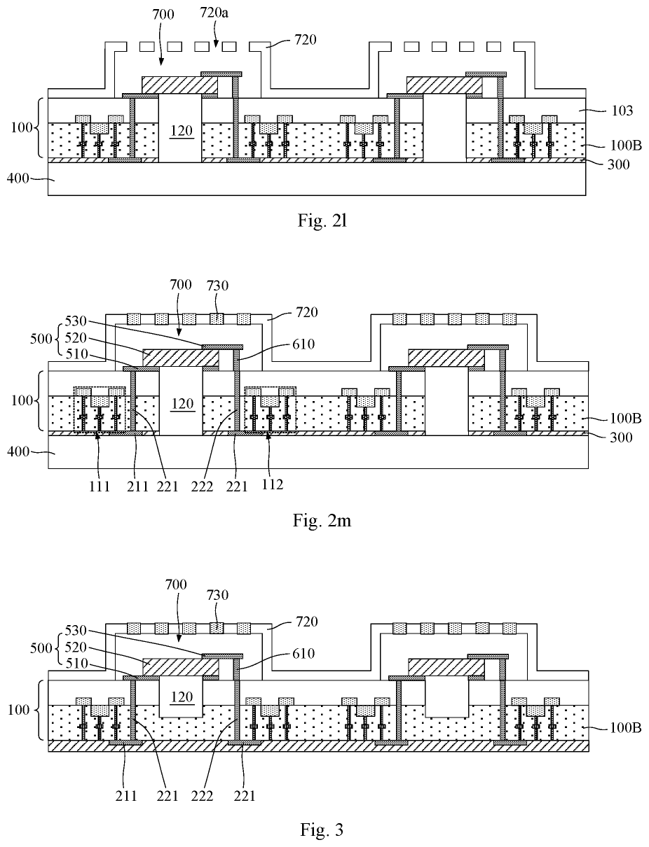

FIG. 1 shows a flowchart schematically illustrating a method for integrating a crystal resonator with a control circuit according to an embodiment of the present invention, and FIGS. 2a to 2m are schematic representations of structures resulting from steps in the method for integrating a crystal resonator with a control circuit according to an embodiment of the present invention. In the following, steps for forming the crystal resonator will be described in detail with reference to the figures.

In step S100, with reference to FIG. 2a, a device wafer 100 is provided, in which a control circuit 110 is formed.

In this embodiment, at least some of interconnecting structures in the control circuit 110 extend to, and are exposed from, a front side 100U of the device wafer 100. Specifically, the device wafer 100 further has a back side 100D opposing the front side 100U, and the interconnecting structures of the control circuit 110 exposed from the surface of the device wafer 100 can be brought into electrical connection with a subsequently formed piezoelectric vibrator and thus be able to apply an electrical signal to the piezoelectric vibrator.

Further, a plurality of crystal resonators may be formed on the device wafer 100 simultaneously. Accordingly, there may be a plurality of device areas AA defined on the device wafer 100, and each crystal resonator may be formed in a respective one of the device areas AA.

Specifically, the control circuit 110 may include a first circuit 111 and a second circuit 112, which may be electrically connected to a top electrode and a bottom electrode of the subsequently formed piezoelectric vibrator, respectively.

With continued reference to FIG. 2a, the first circuit 111 may include a first transistor 111T and a first interconnecting structure 111C. The first transistor 111T may be buried within the device wafer 100, and the first interconnecting structure 111C may be connected to the first transistor 111T and extend to a front side 100U of the device wafer 100. The first interconnecting structure 111C may include conductive plugs electrically connected respectively to a gate, source and drain of the first transistor 111T.

Similarly, the second circuit 112 may include a second transistor 112T and a second interconnecting structure 112C. The second transistor 112T may be buried within the device wafer 100, and the second interconnecting structure 112C may be connected to the second transistor 112T and extend to the front side 100U of the device wafer 100. The second interconnecting structure 112C may include conductive plugs electrically connected respectively to a gate, source and drain of the second transistor 112T.

The formation of the control circuit 110 may include:

providing a substrate wafer 100A, and forming a first transistor 111T and a second transistor 112T on the substrate wafer 100A; and

then, forming a dielectric layer 100B on the substrate wafer 100A to cover the first transistor 111T and the second transistor 112T, and forming a first interconnecting structure 111C and a second interconnecting structure 112C in the dielectric layer 100B, resulting in the formation of the device wafer 100.

In other words, the device wafer 100 includes the substrate wafer 100A and the dielectric layer 100B formed thereon, and a surface of the dielectric layer 100B facing away from the substrate wafer 100A provides the front side 100U. The first transistor 111T and the second transistor 112T are both formed on the substrate wafer 100A. Additionally, the dielectric layer 100B covers the first transistor 111T and the second transistor 112T, and each of the first interconnecting structure 111C and the second interconnecting structure 112C are formed in the dielectric layer 100B and extends to the surface of the dielectric layer 100B facing away from the substrate wafer.

The substrate wafer 100A may be either a silicon wafer or a silicon-on-insulator (SOI) wafer. In this embodiment, the substrate wafer 100A is a SOI wafer including a base layer 101, a buried oxide layer 102 and a top silicon layer 103, which are sequentially stacked in this order in the direction from the back side 100D to the front side 100U.

It is to be noted that, the interconnecting structures of the control circuit extend to the front side 100U of the device wafer, while the piezoelectric vibrator is to be subsequently formed on the back side 100D of the device wafer. Accordingly, a connecting structure may be subsequently formed to lead connection ports of the control circuit 110 from the front to back side of the device wafer and brought into electrical connection with the subsequently formed piezoelectric vibrator there.

Specifically, the connecting structure may include a first connection for electrically connecting the first interconnecting structure 111C to the bottom electrode of the subsequently formed piezoelectric vibrator and a second connection for electrically connecting the second interconnecting structure 112C to the top electrode of the subsequently formed piezoelectric vibrator.

In addition, the first connection may include a first conductive plug 221 having two ends configured to respectively connect to the first interconnecting structure 111C and the subsequently formed bottom electrode. That is, the first conductive plug 221 may serve to lead a connecting port of the first interconnect 111C in the control circuit from a front side of the control circuit to a back side thereof so as to enable electrical connection of the bottom electrode subsequently formed on the back side of the device wafer to the control circuit from the back side of the control circuit.

Optionally, in this embodiment, the first connection may further include a first connecting wire 211 formed, for example, on the front side of the device wafer. The first connecting wire 211 may connect one end of the first conductive plug 221 to the first interconnecting structure, and the other end of the first conductive plug 221 may be electrically connected to the bottom electrode.

In alternative embodiments, the first connecting wire in the first connection may be formed on the back side of the device wafer. In this case, the first connecting wire may connect one end of the first conductive plug 221 to the bottom electrode, and the other end of the first conductive plug 221 may be electrically connected to the first interconnecting structure in the control circuit.

Similarly, the second connection may include a second conductive plug 222 having two ends configured to respectively connect to the second interconnecting structure 112C and the subsequently formed top electrode. That is, the second conductive plug 222 may serve to lead a connecting port of the second interconnecting structure 112C in the control circuit from the front to back side of the control circuit so as to enable electrical connection of the top electrode subsequently formed on the back side of the device wafer to the control circuit from the back side of the control circuit.

In this embodiment, the second connection may further include a second connecting wire 212 formed, for example, on the front side of the device wafer. The second connecting wire 212 may connect one end of the second conductive plug 222 to the second interconnecting structure, and the other end of the second conductive plug 222 may be electrically connected to the top electrode.

In alternative embodiments, the second connecting wire in the second connection may be formed on the back side of the device wafer. In this case, the second connecting wire may connect one end of the second conductive plug 222 to the top electrode, and the other end of the second conductive plug 222 may be electrically connected to the second interconnecting structure in the control circuit.

The first conductive plug 221 in the first connection and the second conductive plug 222 in the second connection may be formed in a single process step. The first connecting wire 211 in the first connection and the second connecting wire 212 in the second connection may also be formed in a single process step.

Specifically, in this embodiment, the formation of the first connection that includes the first conductive plug 221 and the first connecting wire 211 on the front side of the device wafer and of the second connection that includes the second conductive plug 222 and the second connecting wire 212 on the front side of the device wafer may include the following steps:

Step 1: Etching the device wafer 100 from the front side 100U thereof so that a first connecting hole and a second connecting hole are formed, as shown in FIG. 2b. Specifically, compared with the bottom of the control circuit, the bottoms of both the first and second connecting holes may are closer to the back side 100D of the device wafer.

Step 2: Filling a conductive material in the first and second connecting holes, thereby resulting in the formation of the first and second conductive plugs 221, 222, as shown in FIG. 2b.

In this way, compared with the bottom of the control circuit, the bottoms of both the first and second connecting holes are closer to the back side 100D of the device wafer. As a result, the first and second conductive plugs 221, 222 may both extend from the front side of the control circuit 110 to the back side thereof and be able to be connected to the first and second circuits 111, 112, respectively.

Specifically, the first and second transistors 111T, 112T may be formed within the top silicon layer 103 above the buried oxide layer 102, and the first and second conductive plugs 221, 222 may penetrate sequentially through the dielectric layer 100B and the top silicon layer 103 and terminate at the buried oxide layer 102. Thus, it can be considered that the buried oxide layer 102 may serve as an etch stop layer for the etching process for forming the first and second connecting holes. In this way, high etching accuracy can be achieved for the etching process.

In a subsequent process, the device wafer may be thinned from the back side so that the first and second conductive plugs 221, 222 are exposed from the processed back side and brought into electrical connection with the top and bottom electrodes of the piezoelectric vibrator formed on the back side.

Step 3: Forming the first connecting wire 211 that connects the first conductive plug 221 to the first interconnecting structure 111C and the second connecting wire 212 that connects the second conductive plug 222 to the second interconnecting structure 112C on the front side of the device wafer, as shown in FIG. 2b.

In alternative embodiments, the first connecting wire in the first connection and the second connecting wire in the second connection are both formed on the back side of the device wafer, the formation of the first connection that includes the first conductive plug and the first connecting wire and of the second connection that includes the second conductive plug and the second connecting wire may include, for example:

first, etching the device wafer from the front side thereof to form a first connecting hole and a second connecting hole;

then, filling the first connecting hole and the second connecting hole with a conductive material, to form the first conductive plug electrically connected to the first interconnecting structure and the second conductive plug electrically connected to the second interconnecting structure respectively;

subsequently, thinning the device wafer from the back side thereof so that the first and second conductive plugs are exposed; and

forming, on the back side of the device wafer, the first connecting wire that is connected to the first conductive plug at one end and configured for electrical connection with the bottom electrode at the other end and the second connecting wire that is connected to the second conductive plug at one end and configured for electrical connection with the top electrode at the other end.

It is to be noted that although the first and second conductive plugs 221, 222 have been described above as being formed from the front side of the device wafer prior to the formation of the first and second connecting wires 221, 212, they may alternatively formed from the back side of the device wafer subsequent to the thinning of the device wafer, as will be described in greater detail below.

In addition, in a subsequent process, a support wafer may be bonded to the front side 100U of the device wafer 100. Accordingly, subsequent to the formation of the first and second connecting wires 221, 212, the method may optionally further include forming, on the front side 100U of the device wafer 100, a planarized layer 300 which provides the device wafer 100 with a flatter bonding surface.

With reference to FIG. 2c, the planarized layer 300 may be formed on the front side 100U of the device wafer 100 and may have a top surface not lower than those of the first and second connecting wires 221, 212. For example, the planarized layer 300 may be formed to cover the device wafer 100 and the first and second connecting wires 221, 212, and then be planarized. Alternatively, the top surface of the planarized layer 300 may be formed in flush with those of the first and second connecting wires 221, 212 so that it also provides the device wafer 100 with a flatter bonding surface.

In this embodiment, the planarized layer 300 may be formed using a polishing process. In this case, for example, the first and second connecting wires 221, 212 may serve as a polish stop layer such that the top surface of the formed planarized layer 300 is flush with those of the first and second connecting wires 221, 212, and all these surfaces may make up the bonding surface for the device wafer 100.

In step S200, with reference to FIGS. 2c to 2e, a lower cavity 120 with an opening at the back side of the device wafer is formed in the device wafer 100.

In this embodiment, the lower cavity 120 may be formed, for example, using a method including steps S210 and S220 below.

In step S210, with reference to FIG. 2c, the lower cavity 120 of the crystal resonator is formed by etching the device wafer 100 from the front side thereof.

Specifically, the lower cavity 120 extends deep into the device wafer 100 from the front side 100U. Compared with the bottom of the control circuit, the bottoms of both the first and second connecting holes may are closer to the back side 100D of the device wafer.

In this embodiment, the lower cavity 120 may be formed subsequent to the formation of the planarized layer 300 by etching the planarized layer 300 and the device wafer 100. Specifically, during the formation of the lower cavity 120 the planarized layer 300, the dielectric layer 100B and the top silicon layer 103 are etched sequentially and the etching is stopped at the buried oxide layer 102.

Thus, in this embodiment, the buried oxide layer 102 may serve as an etch stop layer for both the etching process for forming the first and second connecting holes for the first and second conductive plugs 221, 222 and the etching process for forming the lower cavity 120. As a result, bottoms of the resulting first and second conductive plugs 221, 222 are at the same or similar level as that of the lower cavity 120. In this way, when the device wafer is subsequently thinned from the back side 100D, the first and second conductive plugs 221, 222 and the lower cavity 12 can be all exposed.

It is to be noted that the relative positions of the lower cavity 120 and the first and second circuits shown in the figures are merely for illustration, and in practice, the arrangement of the first and second circuits may depend on the actual circuit lay-out requirements. The present invention is not limited in this regard.

In step S220, with reference to FIGS. 2d to 2e, the device wafer 100 is thinned from the back side 100D until the lower cavity 120 is exposed.

In this embodiment, the lower cavity 120 is bottomed at the buried oxide layer 102. Therefore, as a result of the thinning of the device wafer, the base layer 101 and the buried oxide layer 102 are sequentially stripped away, and the top silicon layer 103 and lower cavity 120 are both exposed. The exposed lower cavity 120 is configured to provide a space in which the subsequently formed piezoelectric vibrator can vibrate. Moreover, the first and second conductive plugs 221, 222 are also exposed as a result of thinning the device wafer. As such, it is made possible to electrically connect the exposed first and second conductive plugs 221, 222 to the subsequently formed piezoelectric vibrator.

Optionally, with reference to FIG. 2d, before the device wafer 100 is thinned, a support wafer 400 may be bonded to the front side of the device wafer 100 so as to provide a support for the thinning process. At the same time, the support wafer 400 can close the opening of the lower cavity exposed at the front side of the device wafer. Therefore, it can be considered that, in this embodiment, the support wafer 400 also serves as a cap substrate for closing the opening of the lower cavity at the front side of the device wafer.

It is to be noted that, in this embodiment, the lower cavity 120 is formed by etching the device wafer 100 from the front side and thinning the device wafer 100 from the back side so that the opening of the lower cavity 120 is exposed at the back side of the device wafer 100.

However, in other embodiments, referring to FIG. 3, the lower cavity 120 of the crystal resonator may be alternatively formed by etching the device wafer from the back side. In still other embodiments, the etching process on the back side of the device wafer may be preceded by a thinning of the device wafer.

With particular reference to FIG. 3, in one specific embodiment, the formation of the lower cavity by etching the device wafer from the back side thereof may include, for example, the following steps.

At first, the device wafer is thinned from the back side. In case of the substrate wafer being a SOI wafer, this may involve sequential removal of the base layer and the buried oxide layer of the substrate wafer. Of course, the thinning of the substrate wafer may involve partial removal of the base layer, or complete removal of the base layer and hence exposure of the buried oxide layer, or the like.

Next, the device wafer is etched from the back side so that the lower cavity is formed. It is to be noted that the lower cavity resulting from the etching of the device wafer may have a depth as practically required, and the present invention is not limited in this regard. For example, after the device wafer is thinned and the top silicon layer 103 is exposed, the top silicon layer 103 may be etched to form the lower cavity therein. Alternatively, the etching process may proceed through the top silicon layer 103 and further into the dielectric layer 100B, so that the resulting lower cavity 120 extends from the top silicon layer 103 into the dielectric layer 100B.

It is to be also noted that during the formation of the lower cavity as shown in FIG. 3, prior to the formation of the lower cavity, another support wafer may be optionally bonded to the front side of the device wafer to assistantly support the device wafer. Of course, instead of bonding the support wafer, it is also possible to form a plastic encapsulation layer on the front side of the device wafer, which covers all the components exposed on the front side of the device wafer.

As discussed above, in other embodiments, the first conductive plug 221 of the first connection and the second conductive plug 222 of the second connection may be formed from the back side of the device wafer 100 after the thinning of the device wafer.

Specifically, a method for forming the first and second connecting wires on the front side of the device wafer 100, forming the first and second conductive plugs 221, 222 from the back side of the device wafer 100, connecting the first conductive plug 221 to the first connecting wire 211 and connecting the second conductive plug 222 to the second connecting wire 212 may include the steps detailed below.

At first, prior to the bonding of the support wafer 400, the first and second connecting wires 221, 212 that are electrically connected to first and second interconnecting structures, respectively, are formed on the front side of the device wafer 100.

Next, after the device wafer 100 is thinned, it is etched from the back side to form therein first and second connecting holes, both of which extend through the device wafer 100 so that the first and second connecting wires 211, 212 are exposed respectively in the holes.

Subsequently, a conductive material is filled in the first and second connecting holes, resulting in the formation of the first and second conductive plugs 221, 222. The first conductive plug 221 is connected at one end to the first connecting wire 211 and configured for electrical connection with the bottom electrode of the piezoelectric vibrator at the other end. The second conductive plug 222 is connected at one end to the second connecting wire 212 and configured for electrical connection with the top electrode of the piezoelectric vibrator at the other end.

In an alternative embodiment, a method for forming the first and second connecting wires on the back side of the device wafer 100, forming the first and second conductive plugs from the back side of the device wafer 100, connecting the first conductive plug 221 to the first connecting wire and connecting the second conductive plug 222 to the second connecting wire may include the steps detailed below.

At first, the device wafer 100 is thinned from the back side, followed by etching the device wafer 100 from the back side and thus forming first and second connecting holes therein.

Next, a conductive material is filled in the first and second connecting holes, resulting in the formation of the first and second conductive plugs, so that he first conductive plug is electrically connected at one end to the first interconnecting structure, and the second conductive plug is electrically connected at one end to the second interconnecting structure.

Subsequently, the first and second connecting wires are formed on the back side of the device wafer 100, so that one end of the first connecting wire is connected to the other end of the first conductive plug, the other end of the first connecting wire is configured for electrical connection with the bottom electrode, one end of the second connecting wire is connected to the other end of the second conductive plug, and the other end of the second connecting wire is configured for electrical connection with the top electrode.

In step S300, with reference to FIGS. 2f to 2i, a piezoelectric vibrator 500 including a top electrode 530, a piezoelectric crystal 520 and a bottom electrode 510 is formed on the back side of the device wafer 100 (i.e., the surface of the device wafer 100 facing away from the support wafer 400) above the lower cavity 120.

Specifically, the formation of the piezoelectric vibrator 500 may include, for example, the steps as follows:

Step 1: Forming the bottom electrode 510 at a predetermined location on the back side of the device wafer 100, as shown in FIG. 2f. In this embodiment, the bottom electrode 510 is located around the lower cavity 120 and covers the first conductive plug 221. Thus, the bottom electrode 510 is electrically connected to the first circuit 111 via the first conductive plug 221 and the first connecting wire 211, and thus to the first transistor 111T via the first interconnecting structure 111C.

It is to be noted that in alternative embodiments where the first connecting wire of the first connection is formed on the back side of the device wafer, the bottom electrode 510 may be brought into electrical connection with the first connecting wire.

The bottom electrode 510 may be formed of, for example, silver, and the formation may involve successive processes of thin-film deposition, photolithography and etching. Alternatively, the bottom electrode 510 may be formed using a vapor deposition process.

Step 2: Bonding the piezoelectric crystal 520 to the bottom electrode 510, as shown in FIG. 2f, so that the piezoelectric crystal 520 is located above the lower cavity 120, with its peripheral edge portions residing on portions of the bottom electrode 510 over the side walls of the lower cavity 120. As such, part of the piezoelectric crystal 520 is aligned with the lower cavity 120. The piezoelectric crystal 520 may be, for example, a quartz crystal plate.

Step 3: Forming the top electrode 530 on the piezoelectric crystal 520, as shown in FIG. 2h. Similar to the bottom electrode 510, the top electrode 530 may also be formed of, for example, silver, using a vapor deposition process. The top electrode 530 may be brought into electrical connection with the control circuit in a subsequent process.

It is to be noted that, in this embodiment, the bottom electrode 510, the piezoelectric crystal 520 and the top electrode 530 are successively formed over the device wafer 100 using semiconductor processes. However, in other embodiments, it is also possible to form the top and bottom electrodes on opposing sides of the piezoelectric crystal and then bond the three as a whole onto the device wafer.

As described above, in the resulting piezoelectric vibrator 200, the bottom electrode 510 is electrically connected to the first circuit via the first connection, and the top electrode 530 is electrically connected to the second circuit via the second connection.

Thus, the piezoelectric vibrator 500 is electrically connected to the control circuit 110 from the back side thereof, thus allowing the control circuit 110 to apply an electrical signal to the bottom and top electrodes 510, 530 of the piezoelectric vibrator 500 to create an electric field therebetween, which causes the piezoelectric crystal 520 of the piezoelectric vibrator 500 to change its shape. When the electric field in the piezoelectric vibrator 500 is inverted, the piezoelectric crystal 520 will change its shape in the opposite direction. Therefore, when the control circuit 110 applies an AC signal to the piezoelectric vibrator 500, the piezoelectric crystal 520 will change shape alternately in opposite directions and thus alternately contract and expand due to change in direction of the electric field. As a result, the piezoelectric crystal 520 will vibrate mechanically.

The first connection comprises the first conductive plug 221 and the first connecting wire 211. The bottom electrode 510 is located below the piezoelectric crystal 520 and extends out from the piezoelectric crystal 520, so that the bottom electrode 510 covers the first conductive plug 221. In this way, the bottom electrode 510 can be electrically connected to the control circuit by the first connection.

In this embodiment, in addition to the second conductive plug 222 and the second connecting wire 212, the second connection may also include a third conductive plug 610 that is connected to the second conductive plug 222 at the bottom and to the top electrode 530 at the top and supports the top electrode 530.

Specifically, the formation of the third conductive plug 610 in the second connection may include the steps below.

At first, with reference to FIG. 2g, prior to the formation of the top electrode, a plastic encapsulation layer 600 is formed over the back side of the device wafer 100, and the plastic encapsulation layer 600 covers the device wafer 100, with the piezoelectric crystal 520 being exposed therefrom. Exemplary materials for the plastic encapsulation layer 600 may include polyimide.

Next, with continued reference to FIG. 2g, a through hole is formed in the plastic encapsulation layer 600. In this embodiment, the through hole extends through the plastic encapsulation layer 600 up to the back side of the device wafer so that the second conductive plug 222 is exposed in the hole.

Subsequently, a conductive material is filled in the through hole, resulting in the formation of the third conductive plug 610, so that the third conductive plug 610 is electrically connected to the second conductive plug 222 at the bottom and exposed from the plastic encapsulation layer 600 at the top.

Thereafter, with reference to FIG. 2h, the top electrode 530 is so formed as to extend from the piezoelectric crystal 520 over the third conductive plug 610 and thus come into electrical connection with the second conductive plug 222 via the third conductive plug 610.

Afterward, with reference to FIG. 2i, the plastic encapsulation layer 600 is removed.

It is to be noted that in embodiments where the second connecting wire in the second connection is formed on the back side of the device wafer, the third conductive plug of the second connection may be brought into electrical connection with the second connecting wire at the top.

Of course, in alternative embodiments, the second connection comprises the second connecting wire 212, the second conductive plug 222, the third conductive plug, and an interconnecting wire. In such embodiments, the third conductive plug may be connected to the second conductive plug 222 at the bottom and to one end of the interconnecting wire at the top, and the other end of the interconnecting wire may overlap at least part of, and thus come into electrical connection with, the top electrode 530.

Specifically, in these embodiments, the formation of the third conductive plug and the interconnecting wire may include, for example, the steps below.

At first, a plastic encapsulation layer is formed over the surface of the device wafer 100 facing away from the support wafer 400. The plastic encapsulation layer may be formed subsequent to the formation of the top electrode in such a manner that the top electrode 530 is exposed from the plastic encapsulation layer.

Next, a through hole is formed in the plastic encapsulation layer, and the through hole extends through the plastic encapsulation layer to the back side of the device wafer (in this embodiment, the second conductive plug 222 is exposed in the through hole), and a conductive material is filled in the through hole to result in the formation of the third conductive plug that is electrically connected at the bottom to the control circuit (in this embodiment, more exactly, to the second conductive plug 222).

Subsequently, the interconnecting wire is formed on the plastic encapsulation layer. The interconnecting wire covers at least part of the top electrode 530 and extends from the top electrode 530 over the third conductive plug. The plastic encapsulation layer is then removed. Thus, the top electrode 530 is electrically connected to the second conductive plug 222 via the interconnecting wire and the third conductive plug.

In step S400, with reference to FIGS. 2j to 2l, a cap layer 720 is formed over the back side of the device wafer 100, and the cap layer 720 covers the piezoelectric vibrator 500 and delimits an upper cavity 700 of the crystal resonator together with the piezoelectric vibrator 500 and the device wafer 100.

Specifically, the formation of the cap layer 720 that delimits the upper cavity 700 may include, for example, the steps below.

In a first step, with reference to FIG. 2j, a sacrificial layer 710 is formed on the surface of the device wafer 100 and covers the piezoelectric vibrator 500.

In a second step, with continued reference to FIG. 2j, a cap material layer 721 is formed over the surface of the device wafer 100 and wraps the sacrificial layer 710 by covering its top and side surfaces.

The space occupied by the sacrificial layer 710 corresponds to the internal space of the subsequently formed upper cavity. Therefore, a depth of the resulting upper cavity may be adjusted by changing a height of the sacrificial layer. It will be recognized that the depth of the upper cavity may be determined as practically required, and the present invention is not limited in this regard.

In a third step, with reference to FIGS. 2k and 2l, at least one opening 720a is formed in the cap material layer, thus resulting in the formation of the cap layer 720. The sacrificial layer 710 is exposed in the opening 720a. The sacrificial layer is then removed via the opening 720a, resulting in the formation of the upper cavity 700.

As a result, the piezoelectric vibrator 500 is enclosed in the upper cavity 700 so that it can vibrate in the lower and upper cavities 120, 400.

Optionally, with reference to FIG. 2m, the method may further include closing the opening in the cap layer 720, so as to close the upper cavity 700, thus enclosing the piezoelectric vibrator 500 within the upper cavity 120. Specifically, the enclosure of the upper cavity 700 may be accomplished by closing the opening with a closure plug 730.

Furthermore, after the cap layer 720 is formed, the support wafer may be retained as a cap substrate for closing the opening of the lower cavity exposed at the front side of the device wafer. Alternatively, after the cap layer 720 is formed, the support wafer may be removed and a separate cap substrate may be bonded to the front side of the device wafer to close the opening of the lower cavity exposed at the front side of the device wafer.

A structure of the crystal resonator formed according to the above method will be described below with reference to FIG. 2m. The crystal resonator includes:

a device wafer 100, in which the control circuit and a lower cavity 120 are formed, the lower cavity 120 having an opening at a back side of the device wafer;

a piezoelectric vibrator 500 comprising bottom electrode 510, a piezoelectric crystal 520 and a top electrode 530, the piezoelectric vibrator 500 formed on the back side of the device wafer 100 and is in positional correspondence with the lower cavity 120;

a connecting structure formed on the device wafer 100, the connecting structure configured to electrically connect both the top and bottom electrodes 530, 510 of the piezoelectric vibrator 500 to the control circuit; and

a cap layer 720 formed on the back side of the device wafer 100 so as to cover the piezoelectric vibrator 500 and delimit an upper cavity 700 together with the piezoelectric vibrator 500 and the device wafer 100 (the cap layer 720 can be considered as a layer enclosing the piezoelectric vibrator 500 within the upper cavity 700).

Thus, the integration of the crystal resonator with the control circuit is accomplished by forming the crystal resonator through utilizing semiconductor processes to form the piezoelectric vibrator and enclose it within the device wafer 100 containing the control circuit. This is helpful in correcting raw deviations of the crystal resonator such as temperature and frequency drifts. Moreover, the crystal resonator fabricated using the semiconductor processes is more compact in size and thus less power-consuming. Further, the piezoelectric vibrator is allowed to be arranged, and brought into electrical connection with the control circuit, on the back side of the device wafer.

In this embodiment, the control circuit may include a first circuit 111 and a second circuit 112, which are electrically connected to the bottom and top electrodes 510, 530 of the piezoelectric vibrator 500, respectively. The first circuit 111 may include a first transistor 111T and a first interconnecting structure 111C. The first transistor 111T may be buried within the device wafer 100, and the first interconnecting structure 111C may be connected to the first transistor 111T and extend to the front side of the device wafer 100. The second circuit 112 may include a second transistor 112T and a second interconnecting structure 112C. The second transistor 112T may be buried within the device wafer 100, and the second interconnecting structure 112C may be connected to the second transistor 112T and extend to the front side of the device wafer 100.

The connecting structure may include a first connection that connects the first interconnecting structure 111C to the bottom electrode 510 of the piezoelectric vibrator and a second connection that connects the second interconnecting structure 112C to the top electrode 530 of the piezoelectric vibrator.

The first connection may include a first conductive plug 221 which penetrates through the device wafer 100 so as to extend to the front side of the device wafer into electrical connection with the first interconnecting structure at one end and to extend to the back side of the device wafer 100 into electrical connection with the bottom electrode 510 of the piezoelectric vibrator at the other end.

The first connection may further include a first connecting wire 211. In this embodiment, the first connecting wire 221 is formed on the front side of the device wafer 100 and connects the first conductive plug 221 to the first interconnecting structure. In alternative embodiments, the first connecting wire 211 may be formed on the back side of the device wafer 100 and connect the first conductive plug to the bottom electrode.

With this arrangement, the first connecting wire 211 and first conductive plug 221 collaboratively lead a connection port of the first interconnect 111a from the front side of the device wafer 100 to the back side thereof. In this way, the connection port is allowed to be electrically connected to the bottom electrode 510 of the piezoelectric vibrator 500 that is formed on the back side of the device wafer 100.

In this embodiment, the bottom electrode 510 is so formed on the back side of the device wafer 100 so as to laterally extend beyond the piezoelectric crystal over the first conductive plug 221, thus coming into electrical connection with the first conductive plug 221.

The second connection may include a second conductive plug 222 which penetrates through the device wafer 100 so as to extend to the front side of the device wafer 100 into electrical connection with the second interconnecting structure at one end and to extend to the back side of the device wafer 100 into electrical connection with the top electrode 530 of the piezoelectric vibrator at the other end.

The second connection may further include a second connecting wire 212. In this embodiment, the second connecting wire 212 is formed on the front side of the device wafer 100 and connects the second conductive plug 222 to the second interconnecting structure. In alternative embodiments, the second connecting wire 212 may be formed on the back side of the device wafer 100 and connect the second conductive plug to the top electrode.

Likewise, the second connecting wire 212 and second conductive plug 222 collaboratively lead a connection port of the second interconnecting structure 112a from the front to back side of the device wafer 100. Thus, the connection port is allowed to be electrically connected to the top electrode of the piezoelectric vibrator 500 that is formed on the back side of the device wafer 100.

In this embodiment, the second connection may further include a third conductive plug 610 which electrically connects the top electrode 530 to the second conductive plug 222 and hence to the second interconnecting structure in the second circuit 112.

Specifically, the third conductive plug 610 in the second connection may be formed on the back side of the device wafer in such a manner that its one end is electrically connected to the top electrode and the other end is electrically connected to the second conductive plug 222. It can be considered that the top electrode 530 overlaps at least part of the piezoelectric crystal 520 and extends beyond the piezoelectric crystal 520 and covers the top of the third conductive plug 610, thus the top electrode 530 to the second conductive plug 222 are connected by the conductive plug 610.

In alternative embodiments, the second connection may comprise the second conductive plug 222, the second connecting wire 212, the third conductive plug, and an interconnecting wire. In such embodiments, the third conductive plug may be formed on the back side of the device wafer in such a manner that it is electrically connected to the second conductive plug 222 at the bottom. Additionally, the interconnecting wire may cover at least part of the top electrode 530 at one end and overlap the top of the third conductive plug at the other end, thus coming into connection with the third conductive plug. It will be recognized that, in such cases, the third conductive plug also serves to support the interconnecting wire.

With continued reference to FIG. 2m, the crystal resonator may further include a planarized layer 300, which is formed over the front side of the device wafer 100 and has a surface facing away from the device wafer 100 that is not lower than a surface of the first connecting wire facing away from the device wafer.

In this embodiment, the device wafer 100 includes a substrate wafer and a dielectric layer 100B. The first and second transistors 111T, 112T may be both formed on the substrate wafer, and the dielectric layer 100B is so formed on the substrate wafer as to cover both the first and second transistors 111T, 112T. The first and second interconnecting structures 111C, 112C may be both formed in the dielectric layer 100B.

With continued reference to FIG. 2m, in this embodiment, at least one opening is formed in the cap layer 400 and a closure plug 730 is filled in the opening to close the upper cavity 700, thus enclosing the piezoelectric vibrator 500 within the upper cavity 700.

Furthermore, in this embodiment, the lower cavity extends through the device wafer. Accordingly, a cap substrate may be bonded to the front side of the device wafer to close the opening of the lower cavity present at the front side of the device wafer. The cap substrate may be composed of, for example, a silicon wafer.

In summary, in the method for integrating the crystal resonator with the control circuit according to the present invention, the piezoelectric vibrator is formed, and then brought into electrical connection with the control circuit, on the back side of the device wafer, followed by forming the cap layer using planar fabrication processes, which encloses the piezoelectric vibrator within the upper cavity, thus resulting in the formation of the crystal resonator. Obviously, compared with traditional crystal resonators (e.g., surface-mount ones), the crystal resonator fabricated using planar fabrication processes in accordance with the present invention is more compact in size and hence less power-consuming. Moreover, the crystal resonator of the present invention is able to integrate with other semiconductor components more easily with a higher degree of integration. Further, forming the piezoelectric vibrator on the back side of the device wafer allows higher process flexibility for the crystal resonator.

The description presented above is merely that of a few preferred embodiments of the present invention without limiting the scope thereof in any sense. Any and all changes and modifications made by those of ordinary skill in the art based on the above teachings fall within the scope as defined in the appended claims.

1. A method for integrating a crystal resonator with a control circuit, comprising:
providing a device wafer in which a control circuit is formed;
forming, in the device wafer, a lower cavity with an opening at a back side of the device wafer;
forming, on the back side of the device wafer and above the lower cavity, a piezoelectric vibrator comprising a top electrode, a piezoelectric crystal and a bottom electrode;
forming, on the device wafer, a connecting structure configured to electrically connect both the top and bottom electrodes of the piezoelectric vibrator to the control circuit; and
forming, over the back side of the device wafer, a cap layer which covers the piezoelectric vibrator and delimits, together with the piezoelectric vibrator and the device wafer, an upper cavity for the crystal resonator.

2. The method for integrating a crystal resonator with a control circuit according to claim 1, wherein the device wafer comprises a substrate wafer and a dielectric layer on the substrate wafer;
wherein the substrate wafer is a silicon-on-insulator substrate comprising a base layer, a buried oxide layer and a top silicon layer that are sequentially stacked from a back side to a front side of the silicon-on-insulator substrate.

3. (canceled)

4. The method for integrating a crystal resonator with a control circuit according to claim 1, wherein the formation of the lower cavity comprises: etching the device wafer from a front side thereof to form the lower cavity for the crystal resonator; thinning the device wafer from the back side thereof to expose the lower cavity; and bonding a cap substrate to the front side of the device wafer so that the cap substrate closes an opening of the lower cavity at the front side of the device wafer, or
wherein the formation of the lower cavity comprises etching the device wafer from the back side thereof to form the lower cavity of the crystal resonator.

5. The method for integrating a crystal resonator with a control circuit according to claim 4, wherein the device wafer comprises a silicon-on-insulator substrate comprising a base layer, a buried oxide layer and a top silicon layer that are sequentially stacked from a back side to a front side of the silicon-on-insulator substrate, and
wherein the method further comprises, prior to forming the lower cavity by etching the device wafer from the back side thereof, removing the base layer and the buried oxide layer, and forming the lower cavity by etching the device wafer from the back side thereof comprises forming the lower cavity by etching the top silicon layer.

6. The method for integrating a crystal resonator with a control circuit according to claim 1, wherein the formation of the lower cavity comprises: etching the device wafer from a front side thereof to form the lower cavity of the crystal resonator; and thinning the device wafer from the back side thereof to expose the lower cavity, or
wherein the formation of the lower cavity comprises etching the device wafer from the back side thereof to form the lower cavity of the crystal resonator.

7. The method for integrating a crystal resonator with a control circuit according to claim 1, wherein the formation of the piezoelectric vibrator comprises:
forming the bottom electrode at a predetermined location on the back side of the device wafer; bonding the piezoelectric crystal to the bottom electrode; and forming the top electrode on the piezoelectric crystal; or
forming the top and bottom electrodes for the piezoelectric vibrator on the piezoelectric crystal; and bonding the top and bottom electrodes and the piezoelectric crystal as a whole to the back side of the device wafer;
wherein the formation of the bottom electrode comprises using a vapor deposition process or a thin-film deposition process, and wherein the formation of the top electrode comprises using a vapor deposition process or a thin-film deposition process.

8. (canceled)

9. The method for integrating a crystal resonator with a control circuit according to claim 1, wherein the control circuit comprises a first interconnecting structure and a second interconnecting structure, and the connecting structure comprises a first connecting member and a second connecting member,
wherein the first connecting member connects the first interconnecting structure to the bottom electrode of the piezoelectric vibrator, and the second connecting member connects the second interconnecting structure to the top electrode of the piezoelectric vibrator.

10. The method for integrating a crystal resonator with a control circuit according to claim 9, wherein the first connecting member is formed prior to the formation of the bottom electrode, and wherein:
the first connecting member comprises, in the device wafer, a first conductive plug having two ends configured to be electrically connected respectively to the first interconnecting structure and the bottom electrode; or
the first connecting member comprises a first conductive plug in the device wafer and a first connecting wire on the back side of the device wafer, the first connecting wire electrically connected to one end of the first conductive plug, the first interconnecting structure electrically connected to a further end of the first conductive plug, the first connecting wire electrically connected to the bottom electrode; or
the first connecting member comprises a first conductive plug in the device wafer and a first connecting wire on a front side of the device wafer, the first connecting wire electrically connected to one end of the first conductive plug, the bottom electrode electrically connected to a further end of the first conductive plug, the first connecting wire electrically connected to the first interconnecting structure;
wherein the second connecting member is formed prior to the formation of the top electrode, and wherein:
the second connecting member comprises, in the device wafer, a second conductive plug having two ends configured to be electrically connected respectively to the second interconnecting structure and the top electrode; or
the second connecting member comprises a second conductive plug in the device wafer and a second connecting wire on the back side of the device wafer, the second connecting wire electrically connected to one end of the second conductive plug, the second interconnecting structure electrically connected to a further end of the second conductive plug, the second connecting wire electrically connected to the top electrode; or
the second connecting member comprises a second conductive plug in the device wafer and a second connecting wire on a front side of the device wafer, the second connecting wire electrically connected to one end of the second conductive plug, the top electrode electrically connected to a further end of the second conductive plug, the second connecting wire electrically connected to the second interconnecting structure.

11. The method for integrating a crystal resonator with a control circuit according to claim 10, wherein the formation of the first connecting member comprising the first conductive plug and the first connecting wire on the front side of the device wafer comprises:
etching the device wafer from the front side of the device wafer to form a first connecting hole;
filling a conductive material in the first connecting hole to form the first conductive plug;
forming the first connecting wire on the front side of the device wafer, the first connecting wire connecting the first conductive plug to the first interconnecting structure; and
thinning the device wafer from the back side thereof so that the first conductive plug is exposed and becomes available for electrical connection to the bottom electrode of the piezoelectric vibrator; or
forming, on the front side of the device wafer, the first connecting wire electrically connected to the first interconnecting structure;
thinning the device wafer from the back side thereof and forming a first connecting hole by etching the device wafer from the back side thereof, the first connecting hole extending through the device wafer to expose the first connecting wire; and
filling a conductive material in the first connecting hole to form the first conductive plug having one end connected to the first connecting wire, and a further end configured for electrical connection to the bottom electrode of the piezoelectric vibrator;
wherein the formation of the second connecting member comprising the second conductive plug and the second connecting wire on the front side of the device wafer comprises:
etching the device wafer from the front side of the device wafer to form a second connecting hole;
filling a conductive material in the second connecting hole to form the second conductive plug;
forming the second connecting wire on the front side of the device wafer, the second connecting wire connecting the second conductive plug to the second interconnecting structure; and
thinning the device wafer from the back side thereof so that the second conductive plug is exposed and becomes available for electrical connection to the top electrode of the piezoelectric vibrator; or
forming, on the front side of the device wafer, the second connecting wire electrically connected to the second interconnecting structure;
thinning the device wafer from the back side thereof and forming a second connecting hole by etching the device wafer from the back side thereof, the second connecting hole extending through the device wafer to expose the second connecting wire; and
filling a conductive material in the second connecting hole to form the second conductive plug having one end connected to the second connecting wire, and a further end configured for electrical connection to the top electrode of the piezoelectric vibrator.

12. The method for integrating a crystal resonator with a control circuit according to claim 10, wherein the formation of the first connecting member comprising the first conductive plug and the first connecting wire on the back side of the device wafer comprises:
etching the device wafer from the front side thereof to form a first connecting hole;
filling a conductive material in the first connecting hole to form the first conductive plug electrically connected to the first interconnecting structure;
thinning the device wafer from the back side thereof to expose the first conductive plug; and
forming, on the back side of the device wafer, the first connecting wire having an end connected to the first conductive plug, and a further end configured for electrical connection to the bottom electrode; or
thinning the device wafer from the back side thereof and forming a first connecting hole by etching the device wafer from the back side thereof,
filling a conductive material in the first connecting hole to form the first conductive plug, the further end of the first conductive plug electrically connected to the first interconnecting structure; and
forming, on the back side of the device wafer the first connecting wire having an end connected to the one end of the first conductive plug, and a further end configured for electrical connection to the bottom electrode;
wherein the formation of the second connecting member comprising the second conductive plug and the second connecting wire on the back side of the device wafer comprises:
etching the device wafer from the front side thereof to form a second connecting hole;
filling a conductive material in the second connecting hole to form the second conductive plug electrically connected to the second interconnecting structure;
thinning the device wafer from the back side thereof to expose the second conductive plug; and
forming, on the back side of the device wafer, the second connecting wire having an end connected to the second conductive plug, and a further end configured for electrical connection to the top electrode; or
thinning the device wafer from the back side thereof and forming a second connecting hole by etching the device wafer from the back side thereof,
filling a conductive material in the second connecting hole to form the second conductive plug, the further end of the second conductive plug electrically connected to the second interconnecting structure; and
forming, on the back side of the device wafer, the second connecting wire having an end connected to the one end of the second conductive plug, and a further end configured for electrical connection to the top electrode.

13. The method for integrating a crystal resonator with a control circuit according to claim 10, wherein the bottom electrode is formed on the back side of the device wafer, and extends beyond the piezoelectric crystal to come into electrical connection with the first conductive plug.

14-16. (canceled)

17. The method for integrating a crystal resonator with a control circuit according to claim 10, wherein the formation of the second connecting member further comprises:
forming a plastic encapsulation layer on the back side of the device wafer; and
forming a through hole in the plastic encapsulation layer and filling a conductive material in the through hole to form a third conductive plug having a bottom electrically connected to the second conductive plug and a top exposed from the plastic encapsulation layer, and
wherein the top electrode is formed and extends beyond the piezoelectric crystal over the top of the third conductive plug, so as to come into electrical connection with the third conductive plug; or subsequent to the formation of the top electrode, an interconnecting wire is formed on the plastic encapsulation layer, the interconnecting wire having an end covering the top electrode and a further end covering the third conductive plug, and the plastic encapsulation layer is then removed.

18. (canceled)

19. The method for integrating a crystal resonator with a control circuit according to claim 1, wherein the formation of the cap layer delimiting the upper cavity comprises:
forming, on the back side of the device wafer, a sacrificial layer covering the piezoelectric vibrator;
forming, over the back side of the device wafer, a cap material layer that covers top and side surfaces of the sacrificial layer so as to warp the sacrificial layer;
forming at least one opening in the cap material layer to form the cap layer and removing the sacrificial layer via the opening in which the sacrificial layer is exposed, to form the upper cavity; and
closing the opening in the cap layer so as to close the piezoelectric vibrator within the upper cavity.

20. (canceled)

21. An integrated structure of a crystal resonator and a control circuit, comprising:
a device wafer, in which the control circuit and a lower cavity are formed, the lower cavity having an opening at a back side of the device wafer;
a piezoelectric vibrator, comprising a bottom electrode, a piezoelectric crystal and a top electrode, the piezoelectric vibrator formed on the back side of the device wafer and in positional correspondence with the lower cavity;
a connecting structure, formed on the device wafer, the connecting structure configured to electrically connect the top and bottom electrodes of the piezoelectric vibrator to the control circuit; and
a cap layer, formed on the back side of the device wafer so as to cover the piezoelectric vibrator and delimit an upper cavity together with the piezoelectric vibrator and the device wafer.

22. The integrated structure of a crystal resonator and a control circuit according to claim 21, wherein the control circuit comprises a first interconnecting structure, a second interconnecting structure, a first transistor and second transistor, wherein the connecting structure comprises a first connecting member and a second connecting member,
wherein the first connecting member connects the first interconnecting structure to the bottom electrode of the piezoelectric vibrator, and the second connecting member connects the second interconnecting structure to the top electrode of the piezoelectric vibrator;
wherein the first transistor is connected to the first interconnecting structure, and the second transistor is connected to the second interconnecting structure.

23. The integrated structure of a crystal resonator and a control circuit according to claim 22, wherein the first connecting member comprises
a first conductive plug, which penetrates through the device wafer and has an end extending to a front side of the device wafer into electrical connection with the first interconnecting structure and a further end extending to the back side of the device wafer into electrical connection with the bottom electrode of the piezoelectric vibrator;
wherein the second connecting member comprises
a second conductive plug, which penetrates through the device wafer and has an end extending to a front side of the device wafer into electrical connection with the second interconnecting structure and a further end extending to the back side of the device wafer into electrical connection with the top electrode of the piezoelectric vibrator.

24. The integrated structure of a crystal resonator and a control circuit according to claim 23, wherein the first connecting member further comprises a first connecting wire,
which is formed on the front side of the device wafer and connects the first conductive plug to the first interconnecting structure, or
which is formed on the back side of the device wafer and connects the first conductive plug to the bottom electrode;
wherein the second connecting member further comprises a second connecting wire,
which is formed on the front side of the device wafer and connects the second conductive plug to the second interconnecting structure, or
which is formed on the back side of the device wafer and connects the second conductive plug to the top electrode.

25. The integrated structure of a crystal resonator and a control circuit according to claim 23, wherein the bottom electrode is formed on the back side of the device wafer and extends beyond the piezoelectric crystal into electrical connection with the first conductive plug.

26-27. (canceled)

28. The integrated structure of a crystal resonator and a control circuit according to claim 23, wherein the second connecting member further comprises
a third conductive plug, which is formed on the back side of the device wafer and has an end electrically connected to the top electrode and a further end electrically connected to the second conductive plug; or
wherein the second connecting member further comprises
a third conductive plug, which is formed on the back side of the device wafer and has a bottom electrically connected to the second conductive plug; and
an interconnecting wire, which has an end covering the top electrode and a further end covering a top of the third conductive plug.

29-30. (canceled)

31. The integrated structure of a crystal resonator and a control circuit according to claim 21, wherein at least one opening is formed in the cap layer and is filled with a closure plug to close the upper cavity.
